(19) United States
(12) Patent Application Publication
(10) Pub. No.: US 2026/0161103 A1
(43) Pub. Date: Jun. 11, 2026

(54) LASER PROCESSING UNIT

(71) Applicant: ORC MANUFACTURING CO., LTD., Tokyo (JP)

(72) Inventors: Jin SATO, Tokyo (JP); Masahiko FUNAYAMA, Tokyo (JP); Akira NAKAZAWA, Tokyo (JP); Yuken NAKAMOTO, Tokyo (JP); Yuki MASADA, Tokyo (JP)

(73) Assignee: ORC MANUFACTURING CO., LTD., Tokyo (JP)

(21) Appl. No.: 19/076,201

(22) Filed: Mar. 11, 2025

(30) Foreign Application Priority Data
Dec. 9, 2024 (JP) 2024-214108

(51) Int. Cl. G03F 9/00; G03F 7/00

(52) U.S. Cl. CPC G03F 9/7088; G03F 7/70025; G03F 7/70358; G03F 9/7003; G03F 9/7096

(57) ABSTRACT

A laser-processing unit includes: a scanner configured to scan a laser beam over a mask; a mask stage with a mask table, the mask stage configured to move the mask table in a main scanning direction and a sub-scanning direction, a mask being mounted on the mask table; a processing stage with a workpiece table, the processing stage configured to move the workpiece table in the main scanning direction and the sub-scanning direction, a workpiece being mounted on the workpiece table; a projection optical system configured to project a pattern beam that passes through the mask onto the workpiece mounted on the workpiece table; a mask alignment mechanism configured to detect alignment marks on the mask; and a workpiece alignment mechanism configured to detect alignment marks on the workpiece. The workpiece alignment mechanism is attached to a lens barrel of the projection optical system.

### BACKGROUND OF THE INVENTION

### 1. Field of the Invention

The present invention relates to a laser-processing unit, especially, an alignment system for the alignment of a mask and a workpiece such as a substrate.

### 2. Description of the Related Art

In a laser-processing unit or machine, a laser beam is scanned over a mask and a part of the laser beam that passes through a mask pattern is projected onto a workpiece such as a substrate. A laser beam with high energy density melts or evaporates a surface of the workpiece so that a processed pattern is formed in the workpiece.

Suwa et al. (US2021/0046584Al) discloses a laser-processing unit with a line-beam forming optical unit, which forms a laser-shaped line beam. A scanning mechanism moves the line-beam optical unit to scan the line-shaped line beam over a mask.

In the laser-processing unit, an alignment mechanism for capturing alignment marks on a mask is provided adjacent to a mask stage and an alignment mechanism for capturing alignment marks on a substrate is provided adjacent to a processing unit.

### SUMMARY OF THE INVENTION

A laser-processing unit according to the present invention includes: a scanner configured to scan a laser beam over a mask; a mask stage with a mask table, the mask stage configured to move the mask table in a main scanning direction and a sub-scanning direction, a mask being mounted on the mask table; a processing stage with a workpiece table, the processing stage configured to move the workpiece table in the main scanning direction and the sub-scanning direction, a workpiece being mounted on the workpiece table; a projection optical system configured to project a pattern beam that passes through the mask onto the workpiece mounted on the workpiece table; a mask alignment mechanism configured to detect alignment marks on the mask; and a workpiece alignment mechanism configured to detect alignment marks on the workpiece. The workpiece alignment mechanism is attached to a lens barrel of the projection optical system.

### BRIEF DESCRIPTION OF THE DRAWINGS

The present invention will be better understood from the description of the preferred embodiment of the invention set forth below together with the accompanying drawings, in which:

FIG. 1 is a schematic plan view showing a laser-processing unit according to the present embodiment;

FIG. 2 is a schematic front view of the laser-processing unit;

FIG. 3 is a plan view showing an arrangement of a workpiece alignment mechanism seen from a substrate side;

FIG. 4A is an arrangement of the mask alignment mechanism; and

FIG. 4B is an arrangement of the mask alignment mechanism 70 different from FIG. 4A.

### DESCRIPTION OF THE PREFERRED EMBODIMENTS

Hereinafter, the preferred embodiment of the present invention is described with references to the attached drawings.

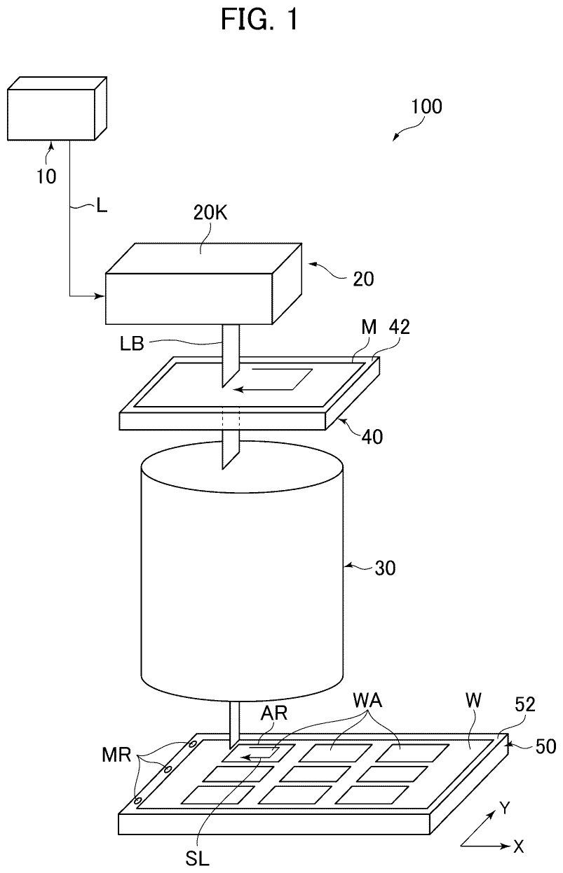

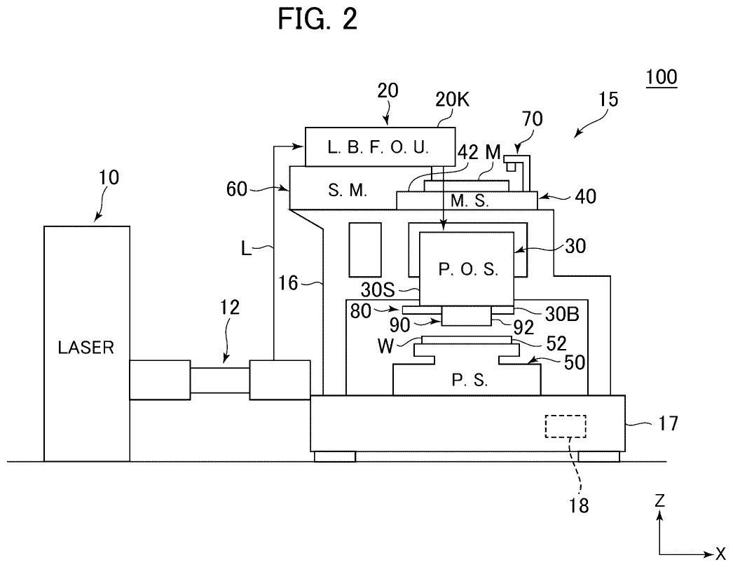

FIG. 1 is a schematic plan view showing a laser-processing unit according to the present embodiment. FIG. 2 is a schematic front view of the laser-processing unit.

A laser-processing unit 100 forms a pattern on a substrate W by laser ablation and is equipped with a line-beam forming optical unit 20, a projection optical system 30, a mask stage 40 and a processing stage 50, which are supported by a body 15 shown in FIG. 2 and movable relative to the body 15. A mask M and a substrate W are mounted on a mask table 42, which is configured on top of the mask stage 40, and a workpiece table 52 of the processing stage 50, respectively. The substrate W is herein a resin substrate such as a printed substrate.

The laser 10 oscillates a laser beam L with high energy density. Herein, the laser 10 is an excimer laser that emits a KrF excimer laser beam in a pulse with the wavelength of 248 nm. The laser 10 is a separate piece of equipment located adjacent to the body 15. The laser beam L oscillated from the laser 10 is directed to the body 15 via a laser delivery system 12. Note that the laser 10 may be provided as an independent light source, which is not part of the laser-processing unit 100.

The line-beam forming optical unit 20 is equipped with a line-beam forming optical system (not shown) including a lens array, a cylindrical lens, an angle switching mirror, etc. The lens array adjusts an intensity distribution of the laser beam L. The line-beam forming optical system forms a line-shaped laser beam LB from the luminous flux of the laser beam L that enters the line-beam forming optical unit 20. The line-shaped laser beam LB is directed to the mask M via a mirror (not shown).

The line-beam forming optical unit 20 has a casing 20K, which contains the above optical system and is supported by the scanning mechanism 60. The scanning mechanism 60 moves the line-beam forming optical unit 20 along the main scanning direction at a given speed to move the line-shaped laser beam LB relative to the mask M along the main scanning direction. Herein, the X axis and Y axis are defined along the main scanning direction and the sub-scanning direction, respectively. Also, the Z axis is defined along the vertical direction.

The mask table 42 moves along the main scanning direction (the X-axis) and the sub-scanning direction (Y-axis direction) and further rotates around the Z-axis direction, by the movement of the mask stage 40. A mask-stage moving mechanism (not shown) moves the mask stage 40 based on signals output from a position-detecting sensor (not shown).

The processing stage 50 functions as a wafer chuck to secure the substrate W to the workpiece table 52 by vacuum suction. Also, the workpiece table 52 moves the substrate W along the main scanning direction (the X-axis direction) and the sub-scanning direction (the Y-axis direction) and further rotates the substrate W around the Z-axis direction, by the movement of the processing stage 50. A processing-stage moving mechanism (not shown) moves the processing stage 50 based on signals output from a position-detecting sensor (not shown).

In the substrate W, a copper wiring layer is formed on an epoxy resin and an insulation layer is further formed on the copper wiring layer. As described above, the laser 10 emits the excimer laser beam with high energy density towards the substrate W, which ablates, i.e., removes material from the substrate W and forms a pattern corresponding to a mask pattern (hereinafter, “processed pattern”) on the substrate W. As for a processed pattern, an interstitial via hole, blind via hole, wiring groove (trench), etc., can be formed on the substrate W.

The projection optical system 30, the mask stage 40, the processing stage 50 and the scanning mechanism 60 are integrally supported by a frame-shaped supporting structure 16 provided in the body 15. The supporting structure 16 is mounted on a base 17.

The scanning mechanism 60 moves the line-beam forming optical unit 20 along the main scanning direction (the X-axis direction). Accordingly, the line-shaped laser beam LB, which is perpendicular to the main scanning direction (the X-axis direction), moves relative to the mask M (the mask stage 40), the projection optical system 30, and the substrate W (the processing stage 50) along the main scanning direction (the X-axis direction). Thus, the mask M mounted on the mask stage 40 and the substrate W mounted on the processing stage 50 are both scanned.

The entire size of the mask pattern formed on the mask M depends upon a processing area AR, in which a processed pattern WA is formed, and a projection magnification of the projection optical system 30. The scanning area of the processing area AR has a dimension greater than the width of the line-shaped laser beam LB along the longitudinal direction. The angle-switching mirror in the line-beam forming unit 20 switches a mirror angle to shift the position of the laser beam LB irradiating the mask M along the sub-scanning direction (the Y axis direction) to repeatedly scan along the main scanning direction (the X-axis direction), as shown by numerical reference “SL”. Thus, a processed pattern WA is formed on the entire processing area AR.

The processing stage 50 moves along the main scanning direction (the X-axis direction) and the sub-scanning direction step by step when one processed pattern WA is formed in the processing area AR. Thus, a laser ablation process over the entire substrate W is carried out. After the laser ablation process for the substrate W is finished, the substrate W is filled with a conductor such as copper.

The laser-processing unit 100 is equipped with a dust collector 90, which removes debris that occurs by melting and evaporation of the surface of the substrate W during laser ablation and scattered around the substrate W. The dust controller 90 has a cylindrical housing 92 arranged between the projection optical system 30 and the processing stage 50. The housing 92 is fixed to the base 30B of a lens barrel 30S.

The laser-processing unit 100 has an off-axis type of alignment mechanism, a mask alignment mechanism 70 and a workpiece alignment mechanism 80. Before laser ablation, the mask alignment mechanism 70 detects alignment marks on the mask M and the workpiece alignment mechanism 80 detects alignment marks on the substrate W. The positions of the mask M and the substrate W, including the rotation angle, are aligned or adjusted based on the positions of the detected alignment marks.

Furthermore, the mask alignment mechanism 70 and the workpiece alignment mechanism 80 detect standard marks MR formed adjacent to the workpiece table 52 (See FIG. 1), independently. A positional relationship between the mask alignment mechanism 70 and the workpiece alignment mechanism 80 is determined, i.e., an alignment is carried out.

The laser-processing unit 100 has a controller 18, which controls the angle-switching mirror in the line-beam forming unit 20, the scanning mechanism 60, the mask-stage moving mechanism, the workpiece-stage moving mechanism, etc. In a laser ablation process, the controller 18 controls the positioning of the mask M and the substrate W, the movement of the line-shaped laser beam LB along the main scanning direction (the X-axis direction), and the switching of the irradiation position of the line-shaped laser beam LB along the sub-scanning direction (the Y-axis direction).

The mask alignment mechanism 70 is attached to the mask stage 40. On the other hand, the workpiece alignment mechanism 80 is attached to the lens barrel 30S of the projection optical system 30. Hereinafter, the above two alignment mechanisms will be explained in detail.

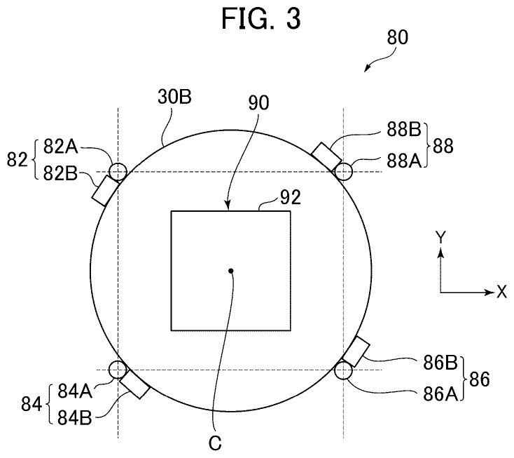

FIG. 3 illustrates an arrangement of the workpiece alignment mechanism 80 as seen from the substrate side toward the projection optical system 30.

The workpiece alignment mechanism 80 has four camera mechanisms 82, 84, 86 and 88, which are arranged around the housing 92 of the dust collector 90. The camera mechanism 82 has a camera 82A and an actuator 82B. The actuator 82B controls and adjusts the position or posture of the camera 82A. The actuator 82B supports the camera 82A so that the camera 82A is located below the base 30B of the lens barrel 30S. The actuator 82B is fixed to the base 30B of the lens barrel 30S.

When starting an operation of the laser-processing unit 100 or carrying out maintenance, the actuator 82B adjusts the position of the camera 82A to adjust the optical axis of the camera 82A. After the adjustment of the optical axis, the camera 82A is fixed to the base 30B. Note that the actuator 82B may have a mechanism that moves the camera 82A along the main scanning direction (the X-axis direction) and the sub-scanning direction (the Y-axis direction). Also, the camera mechanism 82 may have a guide mechanism for moving the camera 82A manually. The camera 82A is not movable after the adjustment of the camera 82A.

Similarly to the camera mechanism 82, the camera mechanisms 84, 86 and 88 have a camera 84A and an actuator 84B, a camera 86A and an actuator 86B, and a camera 88A and an actuator 88B, respectively. The configurations of the camera mechanisms 84, 86 and 88 are the same as the camera mechanism 82.

The camera mechanism 82 and the camera mechanism 84 are attached to the base 30B of the lens barrel 30S so that the camera 82A and the camera 84A are aligned on the same line in the sub-scanning direction (the Y-axis direction). The camera mechanism 86 and the camera mechanism 88 are also attached to the base 30B so that the camera 86A and the camera 88A are aligned on the same line, which is different from the alignment line of cameras 82A and 84A, in the sub-scanning direction (the Y-axis direction). Herein, cameras 82A and 88A are aligned in the main scanning direction (the X-axis direction) and cameras 84A and 86A are aligned in the main scanning direction (the X-axis direction).

The positions of the center axes of the cameras 82A, 84A, 86A and 88A are symmetric with respect to the optical axis C of the projection optical system 30 and the cameras 82A, 84A, 86A and 88A are aligned in both the main-scanning direction (the X-axis direction) and the sub-scanning direction (the Y-axis direction).

When adjusting the alignment of the cameras 82A, 84A, 86B and 88A, the processing stage 50 moves to capture or shooting alignment marks on the substrate W since the cameras 82A, 84A, 86B and 88A are not movable. Note that the workpiece alignment mechanism 80 may have only two camera mechanisms 82 and 84, or camera mechanisms 86 and 88, that are aligned in the sub-scanning direction (the Y-axis direction).

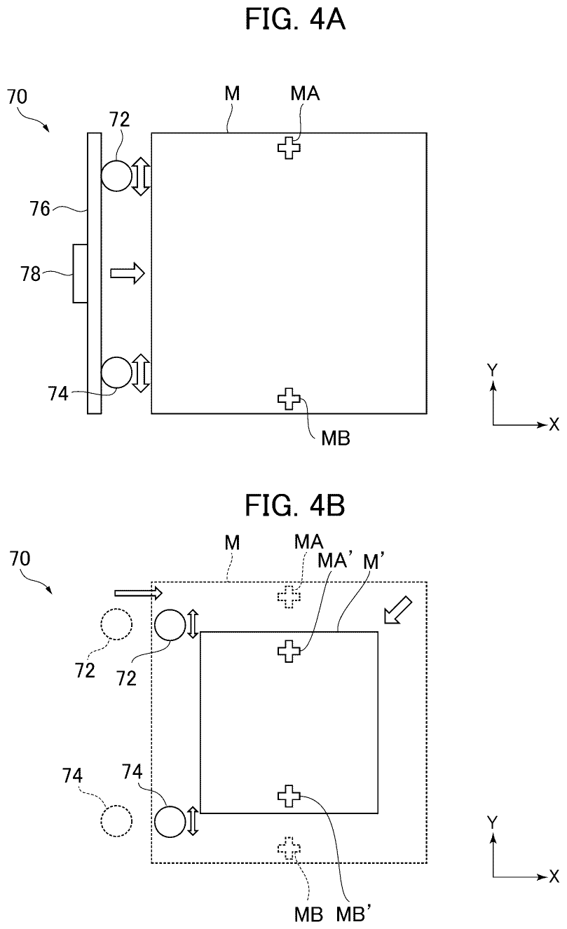

FIG. 4A is an arrangement of the mask alignment mechanism 70. FIG. 4B is an arrangement of the mask alignment mechanism 70 different from FIG. 4A.

The mask alignment mechanism 70 is equipped with two cameras 72, 74 and a guide rail 76. The guide rail 76 guides the movement of the cameras 72 and 74 along the sub-scanning direction (the Y-axis direction). The cameras 72 and 74 are movable along the sub-scanning direction (the Y-axis direction) by actuators (not shown). A movement mechanism 78 moves the guide rail 76 along the main scanning direction (the X-axis direction).

When adjusting the alignment of the cameras 72 and 74, the guide rail 76 is moved along the main scanning direction (the X-axis) and the cameras 72 and 74 are moved along the sub-scanning direction (the Y-axis direction) in accordance to the positions of alignment marks MA and MB on the mask M. After alignment, the guide rail 76 is moved to a reverse direction and the cameras 72 and 74 are moved outside of the scanning area (irradiation area) of the laser beam LB before laser ablation.

As shown in FIG. 4B, when a mask M′ is used instead of the mask M, the cameras 72 and 74 are moved in accordance to the alignment marks MA′ and MB′. Then, the guide rail 76 is moved outside of the scanning area corresponding to the mask M′.

In this way, the laser-processing unit 100 is equipped with the mask alignment mechanism 70 having the movable cameras 72 and 74, and the workpiece alignment mechanism 80 having the camera mechanisms 82, 84, 86 and 88. The cameras 82A, 84A, 86A and 88A, which are provided in the camera mechanisms 82, 84, 86 and 88, respectively, are supported by the actuators 82B, 84B, 86B and 88B, respectively, and the actuators 82B, 84B, 86B and 88B are fixed to the lens barrel 30S.

As described above, the line-shaped laser beam LB repeatedly scans each processing area AR during a laser ablation process. There is a possibility that a deviation could occur in the position of a camera provided in the workpiece alignment mechanism 80.

However, in this embodiment, the workpiece alignment mechanism 80 is supported by the projection optical system 30, i.e., the supporting structure 16, similarly to the mask stage 40 and the processing stage 50. Furthermore, the camera mechanisms 82, 84, 86 and 88 are fixed to the lens barrel 30S. The cameras 82A, 84A, 86A and 88A are not movable during alignment and are not attached to the processing stage 50. Thus, a deviation in the position of a camera in the workpiece alignment mechanism 80 is suppressed while the line-beam forming unit 20 and the processing stage 50 move along the main scanning direction (the X-axis) and the sub-scanning direction (the Y-axis).

In the laser-processing unit 100, an off-axis alignment is applied. The mask alignment mechanism 70 and the workpiece alignment mechanism 80 capture the standard mark MR on the processing stage 50. The positional relationship between the cameras 72 and 74 in the mask alignment mechanism 70 and the cameras 82A, 84A, 86A, and 88A in the workpiece alignment mechanism 80 does not vary with the movement of the processing stage 50 and the line-beam forming unit 20 during a laser ablation process. Thus, the accuracy of the alignment is maintained.

The housing 92 of the dust collector 90, which is provided below the projection optical system 30, covers a processing space, i.e., an irradiation area of the line-shaped laser beam LB. The workpiece alignment mechanism 80 cannot be arranged near to the center position of the substrate W, which corresponds to the position of the optical axis C on the substrate W.

However, since the camera mechanisms 82, 84, 86 and 88 are attached to the lens barrel 30S, the required distance for moving the processing stage 50 during alignment is suppressed. Also, since each of the camera mechanisms 82, 84, 86 and 88 is fixed to the lens barrel 30S, the positional relationship between the cameras 82A, 84A, 86A and 88A is maintained and an accuracy alignment using plural cameras is performed.

The cameras 82A, 84A, 86A and 88A are aligned in the main scanning direction (the X-axis direction) and the sub-scanning direction (the Y-axis direction), which allows the workpiece mechanism 80 to capture or photograph the alignment marks on the substrate W effectively. Especially, the cameras 82A and 84A share the same alignment line, and the cameras 86A and 88A share the same alignment line, respectively, in the sub-scanning direction (the Y-axis direction). Thus, the positional relationship between the cameras 72 and 74 of the mask alignment mechanism 70 and the cameras 82A, 84A, 86A and 88 of the workpiece alignment mechanism 80 can be determined accurately. Note that the number of cameras may be arbitrary, e.g., one camera or two cameras may be applied.

In the mask alignment mechanism 70, the guide rail 76 moves along the main-scanning direction (the X-axis). Thus, a deviation in the positions of the cameras 72 and 74 along the sub-scanning direction (the Y-axis) is suppressed. Also, a retreat position of the cameras 72 and 74 can be selectively adjusted in accordance to the scanning area of the line-shaped laser beam LB or the size of the mask M.

The mask alignment mechanism 70 and the workpiece alignment mechanism 80 may have imagers, sensors or the like that detect the alignment marks, instead of a camera.

Finally, it will be understood by those skilled in the arts that the foregoing description is of preferred embodiments of the device, and that various changes and modifications may be made to the present invention without departing from the spirit and scope thereof.

The present disclosure relates to subject matter contained in Japanese Patent Application No. 2024-214108 (filed on Dec. 9, 2024), which is expressly incorporated herein by reference, in its entirety.

1. A laser-processing unit, comprising:
a scanner configured to scan a laser beam over a mask;
a mask stage with a mask table, said mask stage configured to move said mask table in a main scanning direction and a sub-scanning direction, a mask being mounted on said mask table;
a processing stage with a workpiece table, said processing stage configured to move said workpiece table in the main scanning direction and the sub-scanning direction, a workpiece being mounted on said workpiece table;
a projection optical system configured to project a pattern beam that passes through said mask onto the workpiece mounted on said workpiece table;
a mask alignment mechanism configured to detect alignment marks on said mask; and
a workpiece alignment mechanism configured to detect alignment marks on said workpiece, said workpiece alignment mechanism being attached to a lens barrel of said projection optical system.

2. The laser-processing unit according to claim 1, wherein said workpiece alignment mechanism comprises a plurality of alignment cameras for a workpiece and a plurality of position-adjustment mechanisms, each position-adjustment mechanism configured to support and control a position of a corresponding alignment camera, said plurality of position-adjustment mechanisms being fixed to said lens barrel.

3. The laser-processing unit according to claim 2, wherein said plurality of position-adjustment mechanisms support said plurality of alignment cameras, respectively, to position said plurality of alignment cameras below a base of said lens barrel.

4. The laser-processing unit according to claim 1, wherein said workpiece alignment mechanism comprises two alignment cameras for a workpiece, said alignment cameras aligned in the sub-scanning direction.

5. The laser-processing unit according to claim 1, wherein said workpiece alignment mechanism comprises four alignment cameras for a workpiece, said alignment cameras aligned in the main scanning direction and the sub-scanning direction.

6. The laser-processing unit according to claim 1, wherein said workpiece alignment mechanism comprises a plurality of alignment cameras, said plurality of alignment cameras being arranged around a dust collector provided below a base of said lens barrel.

7. The laser-processing unit according to claim 1, wherein said mask alignment mechanism comprises:
a guide rail extending along the sub-scanning direction;
a plurality of detectors configured to detect a plurality of alignment marks on said mask, said plurality of detectors being movable along the guide rail; and
a moving-mechanism configured to move said guide rail along the main-scanning direction.

8. The laser-processing unit according to claim 1, wherein said processing stage comprises at least one standard mark, the standard mark being located adjacent to said workpiece table and moves with said workpiece table, said mask alignment mechanism and said workpiece alignment mechanism detecting said standard mark independently.

9. The laser-processing unit according to claim 1, further comprising:
a line-beam forming optical unit configured to form a line-shaped laser beam from a laser beam oscillated from a light source; and
a scanning mechanism configured to move said line-beam forming optical unit along the main scanning direction.
